(19) United States
(12) Patent Application Publication
(10) Pub. No.: US 2007/0029632 A1
(43) Pub. Date: Feb. 8, 2007

(54) Radiation sensor, waver, sensor module, and method for the production a radiation sensor

(76) Inventors: Martin Hausner, Wiesbaden (DE); Jurgen Schilz, Niedernhausen (DE); Fred Plotz, Taunusstein (DE); Hermann Karagozoglu, Wiesbaden (DE)

Correspondence Address: WOOD, HERRON & EVANS, LLP, 2700 CAREW TOWER, 441 VINE STREET, CINCINNATI, OH, 45202, US

(21) Appl. No.: 10/555,713

(22) PCT Filed: May 6, 2004
(86) PCT No.: PCT/EP04/04841

§ 371 Date: Oct. 20, 2006

(30) Foreign Application Priority Data
May 7, 2003 (DE) 103203575

(51) Int. Cl. H01L 31/0203

(52) U.S. Cl. 257/434; 257/459; 257/E31.093

(57) ABSTRACT

A radiation sensor (10) comprises a support (1), a cavity (2) which may be a recess or a through hole formed in one surface of the support (1), a sensor element (4, 4a, 4b) formed above the cavity (2), preferably on a membrane (3) covering the cavity (2), and electric terminals (5, 5a, 5b) for the sensor element (4, 4a, 4b). The cavity (2) in the surface of the support (1) has a fully or partly rounded contour (2a).

The invention relates to a radiation sensor, a waver, a sensor module and a method for manufacturing a radiation sensor according to the preambles of the independent claims.

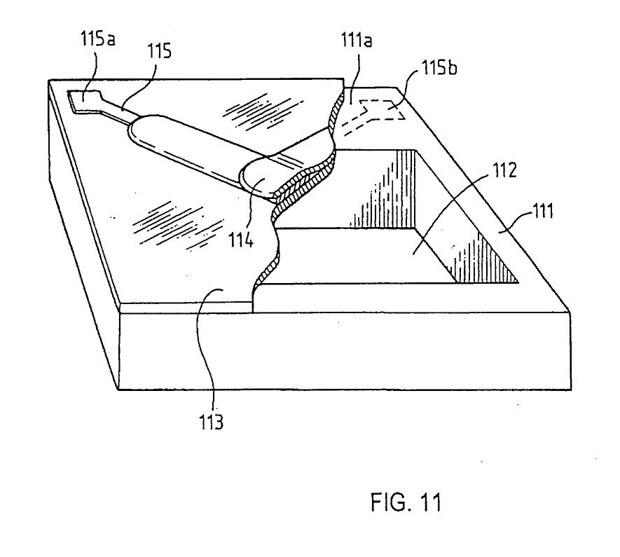

A class of radiation sensors may be designed so that incident radiation, for example infrared radiation (λ>700 nm), causes changes by heating a sensor element which generates an electric signal in accordance with the temperature or a change of the temperature. Since the temperature change will frequently be relatively small a good thermal isolation of the actual sensor element is required to restrict the diffusion of the comparatively low incident amount of heat to non-heat sensitive regions (the thermal short-circuit) to a minimum. It is known to provide a thin membrane on a frame and to form the sensor element on said thin membrane so that the sensor element itself will not directly contact massive heat valleys. A typical embodiment is shown in FIG. 11: a frame, for example of silicon, surrounds a rectangular cavity 112 which may as well be a through hole. A membrane 113 is stretched and fixed above the cavity 112, a sensor element 104 being mounted on the membrane so that the electrically effective area is located on the membrane and not above a massive heat valley. Contacts 105 reach under the poles of the sensor element 114 and can be used to electrically extract the resulting electric signals. The bonding pads 115a, b of the contacts are located above the frame, typically above a broadened bar 101a of the frame, so that the membrane 113 is not damaged during the bonding process. Typically the dimensions of the sensor elements include edge lengths of a few millimetres, cavity diameters of 50 to 90% of the edge lengths of the sensor elements and membrane thicknesses of a few micrometers. A disadvantage of this construction is that, due to the corners of the cavity 112, the suspension of the membrane is discontinuous in said corners so that distortions and creases may occur. Above that comparatively broad bridges need to be provided for the bonding pads of the contacts 115 so that the overall construction becomes relatively “large”.

Furthermore pressure sensors are known in which a more or less round hole is formed in a substrate. The hole is entirely covered by a membrane which is shifted in accordance with a differential pressure between the front and rear sides which may, for example, be capacitively, galvanically or piezoresistively evaluated. The geometric dimensions of such sensors are usually substantially larger than those of radiation sensors so that the requirements in manufacturing precision relating to the formation of the hole can be kept less strict. And in case of small pressure sensors the membranes covering the hole are thicker and more resistant (since they have to bear a mechanic force) than in radiation sensors so that in this respect as well the formation of the hole may be carried out in a different and in particular cruder way.

A selective removal of material from the surface of a substrate may generally be effected by masking the surface areas from which nothing is to be removed and by subjecting the remaining exposed areas to an etching agent. Starting from the unmasked sections the material may then be removed into the depth of the substrate. In this connection, however, several problems may be encountered:
The etching agent will not only etch away the exposed surface areas but also the mask material. Depending on the influence time a dilution or a complete removal of the mask and after that a removal of the substrate surface to be protected may occur.
Under-etching may occur. This means that lateral etching under the mask takes place from the sidewalls of the formed cavity so that the edges under the mask layer seem ragged and not clearly defined. Besides, the walls of the resulting cavity are not smooth.
Unequal etching rates within a single cavity and/or across a plurality of cavities on a substrate result in undefined depths.
Undesirable re-deposition of the etched material. Substrate and/or mask material which has been etched away may be deposited in an undesirable way or in unfavourable positions on the substrate and/or the etching device and may lead to useless results or etching devices which do no longer function.
During the fabrication of deep cavities (depth T>200 μm) the etching rate may be too low to lead to economically useful results.

Etching processes can be isotropic (i.e. have the same effect in all directions) or anisotropic (more effective in certain special directions than in others). Wet etching is generally an isotropic etching process which is, however, relatively slow and unsuitable for etching deeper cavities, for example in a silicon wafer. Anisotropic wet etching is industrially used for etching cavities, however, with the drawback of an oblique angle which results in a loss of space or geometric disadvantages. This process is also relatively slow, but a plurality of wafers can be processed simultaneously.

Dry etching has a higher etching rate (removal per time unit). Here etching plasma (for example SF₆) is prepared and applied to the areas to be etched. Here “plasma” also relates to highly ionised (not fully ionised) states of aggregation. It is also referred to as RIE (“reactive ion etching”). When deep cavities are to be prepared this is referred to DRIE (“deep reactive ion etching”) if dry etching is used. In this case special requirements are posed to the homogeneity of the etching process and the robustness of the mask material. A further increase of the etching rate can be obtained with ICP etching. Here highly ionised plasma is generated by inductive energy coupling (ICP=inductively coupled plasma). The etching rates are so high in this case that with the usual mask layers of polymers or oxides only small cavity depths can be reached before the mask layer is etched away together with the substrate.

On the other hand the utilisation of mask layers containing or fully consisting of (>98 weight percent) metallic materials, particularly aluminium, is known. They have the property to be so robust even in case of thin mask layers that deep cavities can be produced without the mask layer being prematurely removed. However, material from the mask layer is also etched away. It is inter alia deposited in the etching device and also on and in the pipes carrying the inductive coupling. They will then become metallically conductive so that the inductive coupling and therefore the etching rate is initially deteriorated and will finally collapse. The result is an expensive and complicated cleaning of the apparatus.

Under-etching the mask layer is prevented by a method known from the U.S. Pat. No. 5,501,893. Briefly explained an alternating supply (with a periodicity of a few seconds) of an etching gas and a passivation gas to the surface to be etched is effected in this case. In case of a suitable layout the passivation agent in the passivation gas is disposed on the side walls of the cavity so that the etching gas will etch away only the bottom of the cavity so that under-etching is avoided and approximately vertical walls are formed.

It is the object of the invention to provide a radiation sensor, a wafer, a sensor array, a sensor module and a method for manufacturing a radiation sensor which result in a comparatively small and mechanically stable radiation sensor.

Said object is solved by the features of the independent claims. The depending claims relate to preferred embodiments of the invention.

A radiation sensor comprises a support in one surface of which a cavity in the form of a depression or a through hole is formed. Above the cavity a membrane fully or partly covering the cavity is formed, the membrane being fixed to the support. On the membrane the actual sensor element is provided. The cavity on the surface of the support has a fully or partly rounded contour. In particular the contour may be round, circular or oval. It may also have corners. It need not be defined by straight lines.

While the cavity in the support of the radiation sensor has fully or partly rounded contours, the outer contour of the support is preferably rectangular or square. However, for example rhombic, triangular or hexagonal outer contours and oval holes or the like are also feasible. In the corner sections of the radiation sensor electric contacts, particularly their bond pats, may be provided. The bond pats may in particular be located at the diagonally opposed comers of the radiation sensor, and they are at least partially or fully not disposed above the cavity but above the massive support, particularly at the angle between the round contour of the cavity and the corner of the outer contour of the support. The cavity may be produced by etching from the rear side, particularly by reactive ion etching (RIE) or by DRIE (deep reactive ion etching). ICP etching may also be used (ICP=“inductively coupled plasma”). Here high etching rates are obtained.

The sensor element may be a thermopile which, in particular, has hot and cold contacts, the hot contacts being provided above the cavity on the membrane.

During the production of the radiation sensors a plurality of sensors is formed on a wafer which is then separated or cut into individual radiation sensors or sensor arrays including a plurality of radiation sensors after etching the cavities. The arrangement of the radiation sensors or their blanks on the wafer or in the sensor array may follow a rectangular, preferably square grid or also a rhombic grid.

A sensor module comprises a radiation sensor formed as described above or a sensor array formed as described above and further a housing in which the radiation sensor or the sensor array is disposed, an optical window in the housing and electric terminals.

Individual embodiments of the invention will be described below with reference to the drawings in which:

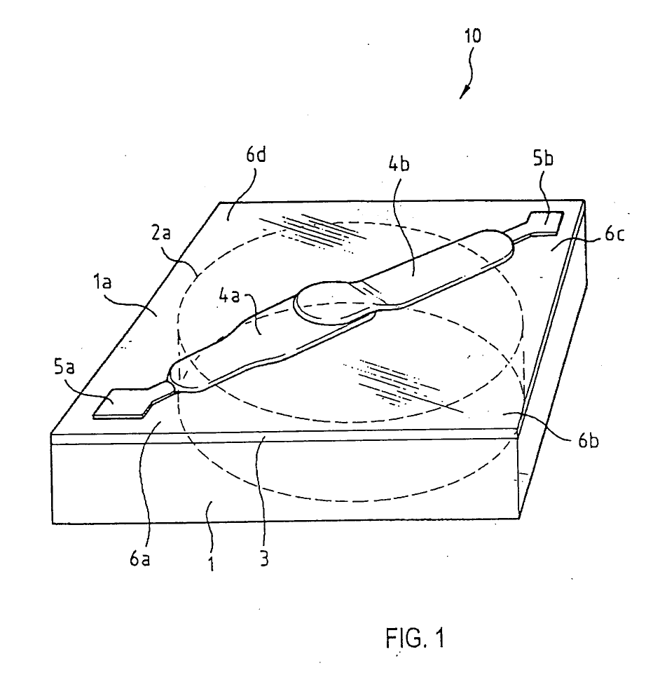

FIG. 1 is a perspective view of a radiation sensor element;

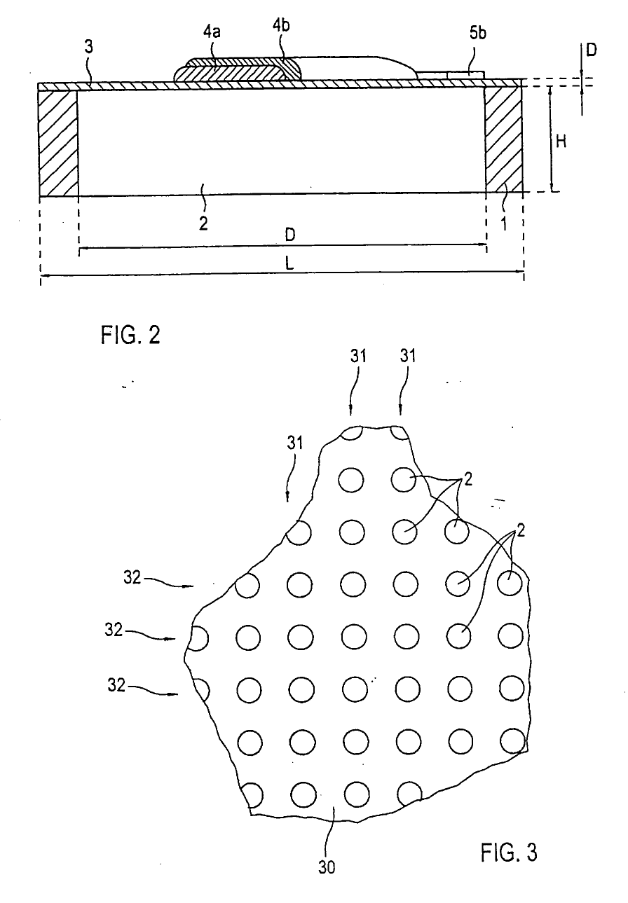

FIG. 2 is a cross sectional view of the arrangement according to FIG. 1;

FIG. 3 is a schematic bottom view of a wafer;

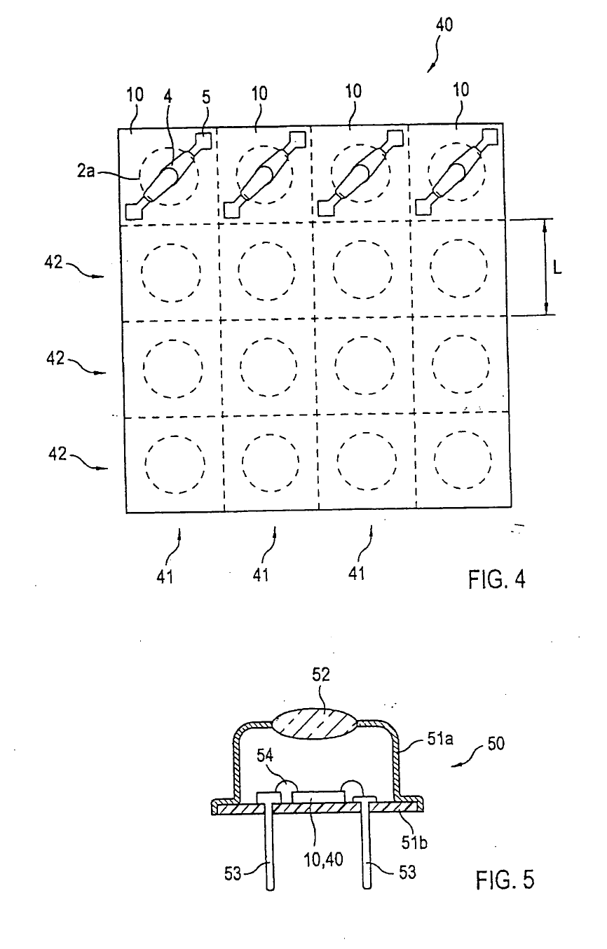

FIG. 4 is a schematic top view of a sensor array;

FIG. 5 a cross sectional view of a sensor module;

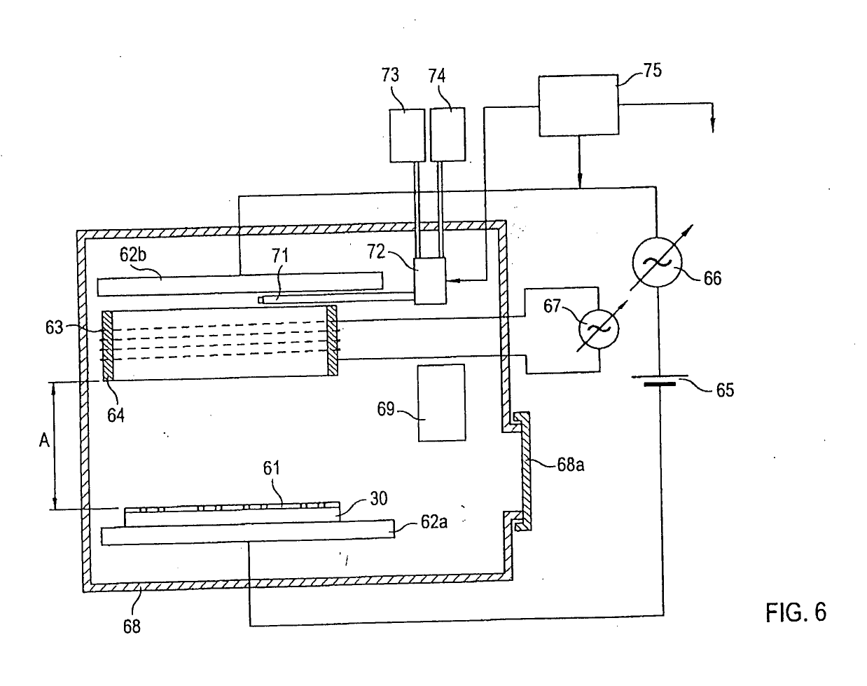

FIGS. 6 to 9 are views for explaining the etching process;

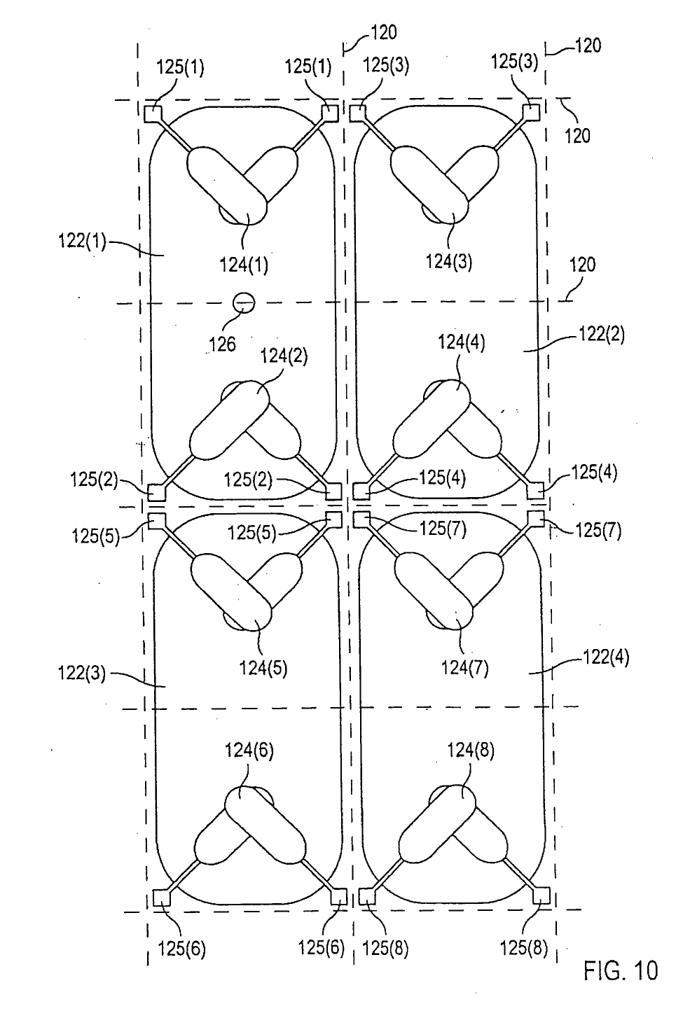

FIG. 10 shows another embodiment; and

FIG. 11 is a schematic view of a known radiation sensor.

FIG. 1 is a schematic perspective view of a radiation sensor according to the invention. On the surface of a support 1 a membrane 3 is formed. Said membrane fully or partly covers the cavity 2, which is to be clearly seen in the cross sectional view of FIG. 2. The support 1 then has the form of a frame if the cavity 2 is a through hole, and the membrane 3 is fully or partly stretched over the frame at one of its main surfaces. In this connection it is to be noted that the frame does not need to be closed on all sides, it may also have open sections, for example at one side.

The cavity 2 has a fully or partly rounded contour 2a at the surface of the support 1. In FIG. 1 the contour 2a is indicated by a broken line since it is not visible in the perspective view of FIG. 1 as it is covered by the membrane 3. In FIG. 1 the special case of a fully rounded contour 2a of the cavity 2 is shown. The contour may be circular or oval. The support 1 itself, however, may have an outer contour 1a which is at least partly or fully defined by straight lines, particularly rhombic, rectangular or square. In the sections 6a-d of the corners of the support therefore comparatively “massive areas are formed, i.e. the support 1 is not recessed here. Above said area the bond pats or generally the electric contacts of the terminals 5, 5a, 5b may be provided. If the bond pats of the electric terminals 5a, 5b are disposed above the massive part of the frame 1 the subsequent connection of said areas to bonding wires will be mechanically less critical.

The actual sensor element 4, 4a, 4b having a certain characteristic relating to a temperature or a temperature change and an electric value, e.g. a voltage, is located on the membrane 3, in particular partly above the cavity 2. It may be a thermopile. The heat-sensitive area of the sensor element is entirely or partly disposed on the membrane and above the cavity 2. Therefore the heat-sensitive section is thermally insulated against heat valleys. Particularly the support 1 itself would act as a heat valley and therefore massively reduce the signal intensity if no thermal insulation were given.

The cavity 2 may be a through hole fully penetrating through the support 1, or it may only be a pan-shaped recess which also has a fully or partly rounded contour on the surface and which is fully or partly covered by the membrane 3.

FIGS. 1 and 2 show that the sensor element 4 itself may be composed of a plurality of components 4a, 4b. The electric terminals 5 may be suitably formed and located metal layers, for example aluminium or copper layers which, on the one hand, have areas accessible from the outside, for example bond pats, and, on the other hand, terminals connected to the actual sensor element 4, 4a, 4b.

The material for the support comprises silicon and/or gallium arsenide and/or other potentially semi-conductive materials. The material for the membrane comprises one or more dielectric layers, e.g. silica and/or silicon nitride, or it is entirely composed of one or both of these materials.

The dimensions of the radiation sensor may satisfy one or more of the following specifications: height H of the support (in cross section)>50 μm, preferably >200 μm, <1,500 μm, preferably y 600 μm, edge length L of one or both edges of the support 1<3 mm, preferably <1.5 mm, preferably <1 mm, diameter D of the cavity >55%, preferably >65%, <90%, preferably <80% of the support edge length L, thickness of the membrane <3 μm, preferably <2 μm, preferably <1 μm.

FIG. 3 shows a section of a wafer 30 during the production of the described radiation sensors 10. The wafer is shown from the “bottom side” which means that the side which will later become the bottom side of the radiation sensors 10, i.e. the bottom side according to FIGS. 1 and 2 is shown. In FIG. 3 it can be seen that many cavities 2 are formed as a matrix or will be formed in a matrix-like way during the etching process. Each individual cavity 2 corresponds to an individual future radiation sensor 2. Even before the etching process the layer subsequently forming the membrane 3 may be formed on the other side of the wafer, and between the surface of the wafer and the membrane layer possibly an additional etching stop layer may be formed for stopping the etching process when the etching agent reaches the membrane layer or the etching stop layer “from the bottom side”.

It can be seen that the preferably oval or round and particularly the circular cavities are preferably arranged in a rectangular or square grid. The determination of the positions to be etched in accordance with the individual cavities 2 is effected by a suitable masking to be described later. The matrix-like arrangement of the cavities 2 corresponding to the individual radiation sensors 10 is effected along columns 31 and rows 32 on the wafer 30.

FIG. 4 schematically shows a sensor array 40—from the top again. The array 40 comprises a plurality radiation sensors 10, 4×4 in the example shown, which are arranged along four columns 41 and four lines 42. They respectively comprise the actual sensor element 4 and suitably located contact surfaces 5. They are each formed as described above, respectively. They may, but need not be identical. With such sensor arrays together with the optic system shown a positional resolution relating to a radiation source to be detected by the radiation sensors becomes possible. The sensor array 40 as a whole may be cut from a wafer 30 like the one shown in FIG. 3. In contrast to FIG. 4 the electric terminals 5 of the individual sensor elements 4 of the radiation sensors 10 of the array 40 may be located in the circumferential areas of the array 40. The contact surfaces for all radiation sensors may, in particular, be provided in the area of the outer sensor element 10.

FIG. 5 shows a sensor module 50. In the sensor module a radiation sensor 10 or a sensor array 40 is provided. In addition further circuit components may be provided in the module 50, such as multiplex devices or analogue/digital converter devices and digital memories and processors for signal processing and transmission. The module further comprises electric terminals 53 which protrude from the housing and are more or less directly connected to the sensor elements or radiation sensors or the sensor array or related electronic devices, for example, via bond pats 54.

The module comprises a housing 51a, 51b consisting, for example, of a bottom plate 51b and a cup 51a slipped over it. The housing may be a standard housing, for example a TO5 or the like. Further a radiation window 52 enabling the impingement of the radiation to be detected is provided in the housing. In addition an optical projection element may be provided for focussing the impinging radiation onto the surface of the radiation sensor or the array. For example, a lens 52 may be provided which acts to realise both the transmissibility for radiation and focussing/projection. However, for example, a mirror with the focus in the plane of the sensor array may also be provided.

A method for manufacturing a radiation sensor 10 may comprise the following steps:

Production of a plane wafer. The wafer consists of the material of which the support of the radiation sensor is to consist. The wafer may be large enough to enable the simultaneous production of a plurality radiation sensors arranged in a matrix array. The wafer may have a thickness which corresponds to the height h of the resulting radiation sensor. To the future upper side (the upper side according to FIGS. 1 and 2) of the wafer then an etching stop layer is applied, and above it a mechanically stable layer which later forms the membrane 3.

To the other surface of the wafer then an etching mask is applied which has openings the contour of which corresponds to the desired contour 2a of the cavity 2 in the substrate 1. Therefore the etching mask also comprises openings having a fully or partially rounded contour.

Then the wafer is etched, preferably dry etched, from the side of the wafer coated with the etching mask, until the wafer is etched through, i.e. until the etching stop layer on the other surface of the wafer is reached.

At suitable times during the manufacturing process the metal layers for the electric terminals 5 are applied, the actual sensor elements 4 are attached, and the wafer is cut into individual radiation sensors or sensor arrays comprising a plurality of radiation sensors.

In the following a removing process as well as a mask material for a substrate such as the above mentioned wafer and a substrate or wafer comprising such a mask material will be described. The technology described here may be used to manufacture the described radiation sensors.

It particularly relates to the deep structuring in silicon or germanium or generally in a semiconductor or a material suitable for a semiconductor substrate.

For manufacturing a cavity, for example in a substrate for a radiation sensor 10 such as the one described above a dry etching method is used here. It is particularly suitable for forming cavities having fully or partly rounded contours since the etching direction is not influenced by crystal orientation. Before the removal is initiated the wafer is totally or partly masked with a metallic material, preferably aluminium or certain alloys. Finally measures are taken to prevent the re-deposition of the etched mask material (metal), particularly on the etching device. Preferably inductive energy is coupled to the etching medium during the etching process (IPC). Here the prevention of a re-deposition on sensitive components of the device may be achieved by keeping the substrate sufficiently far away from the inductive coupling. The distance should be at least 8, preferably at least 10, preferably at least 13 cm. The distance may as well be at least twice, preferably at least trice the average free path length of the plasma atoms. The depth of the cavity to be produced is preferably at least 80 μm, preferably at least 150 μm, preferably at least 300 μm. Etching may also be carried out through the entire wafer (down to the etching stop layer on the other side of the wafer).

FIG. 6 shows the conditions during the etching process. 68 designates a vacuum container which is evacuated during the etching process. The pressure during the etching process is preferably less than 5 Pa, preferably less than 3 Pa. An opening 68a is provided for the insertion and subsequent removal of a wafer 30 carrying a mask 61. The wafer 30 carrying the mask 61 is placed on a table here schematically shown as a plate 62a of a capacitor the opposed plate 62b of which is mounted at the upper side of the chamber 68. During the etching process a direct voltage 65 of preferably 20-100 V as well as an alternating current 66 (with a frequency of, for example, 13.56 MHz) are applied to the capacitor. 71 designates a gas inlet for introducing, on the one hand, an etching gas, and, on the other hand, possibly also a passivation gas between the plates 62a, 62b of the capacitor. To this end a flow control 72 is provided which alternatingly supplies the one or the other gas to the outlet 71 from the corresponding storage containers 73 and 74.

The inductive energy coupling is effected by a coil 63 with few windings (number n of the windings <6, preferably <4). Said coil is disposed on a, for example, tube-shaped substrate 64 which may consist of a dielectric material such as alumina, aluminium nitride, quartz, silica glass, quartz glass or mixtures containing one or more of said materials, and an alternating voltage having a frequency of, for example, 13.56 MHz or generally in a range of 4 MHz to 41 MHz and a power of 0.5 to 5 KW is supplied to the coil. The etching rate is preferably more than 1 μm/min, preferably more than 2 μm/min.

The substrate 64 may be provided directly on or under the plate 62b of the capacitor. A plurality of permanent magnets may be provided which may be connected in series so that the north and south poles alternate. A plurality of permanent magnets (not shown) may be provided on the circumference, preferably in regular intervals and further preferably outside of the support 64. The poles of the magnetic field generated by the permanent magnets may be spaced in the axial direction of the substrate 64. The permanent magnets may be oblong, and they may extend in the axial direction of the substrate 64 or in the direction of the gas flow. The magnets may, in this case, be distributed around the circumference in an alternating pattern so as to be anti-parallel (N-S, then S-N, then N-S again). The permanent magnets have the function to equalise the inductive effect for the ions and electrons and to reduce the absolute value of the electron temperature at the wafer.

69 denotes other components within the vacuum container 68, for example handling devices or the like. A control or regulator device 75 controls or regulates the individual components. The pump for evacuating the container during operation is not shown.

The mask 61 of the wafer 30 contains or fully consists of (>98 weight percent) a metallic material or an alloy, preferably comprising aluminium. The distance A between the surface to be etched and the lower edge of the coil substrate 64 or the coil 63 itself is at least 8 cm, preferably at least 10 cm, preferably at least 12 cm or at least twice the average free path length of the etching atoms, preferably at least trice the average free path length. This ensures the prevention of a re-deposition of the etched aluminium on the inner wall of the coil substrate 64. Therefore it will not become conductive and thus not block the coupled magnetic field.

The mask may alternatively or in addition to aluminium also comprise Cr or Ni or Pt or Au or Fe as main component (>90 weight percent, preferably >96 weight percent). Aluminium or nickel alloys may also be used, e.g. AlCu, AlSi, AlTi, NiFe, NiCr or the chromium alloy CrAu. Particularly the following alloys are feasible as mask material:
AlNiFe, e.g. 11-13 Al, 21-23 Ni, remainder Fe, “AlNi 090”,
AlNiFe, e.g. 13-15 Al, 27-29 Ni, remainder Fe, AlNi 120”,
AlNiCo, e.g. 9-11 Al, 19-21 Ni, 14-16 Co, >1 CuTi, remainder preferably Fe “AlNiCo 160”,
AlNiCo, e.g. 11-13 Al, 18-20 Ni, 14-16 Co, 3-5 Cu, remainder preferably Fe “AlNiCo 190”,
AlCu, e.g. 0.5-2 Cu, remainder Al,
AlSi, e.g. 0.5-2 Si, remainder Al,
AlTi, e.g. max. 3, preferably max. 1.5 Ti, remainder Al,
NiFe, e.g. 35-37 Ni, remainder Fe, “Hyperm 36 M”,
NiFe, e.g. 49-51 Ni, remainder Fe, “Hyperm 52 k”,
NiCr, e.g. 78-82 Ni, remainder Cr,
CrAu, e.g. 45-55 Cr, remainder Au.

The above dimensionless figures are weight or volume percent values. Particularly preferred are the respective average values of the indicated ranges.

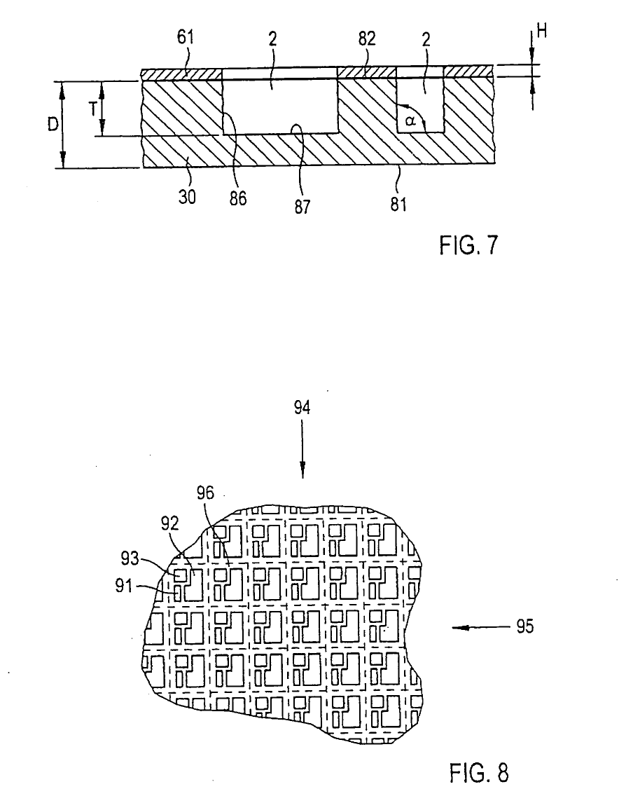

FIG. 7 is an enlarged schematic cross sectional view of the wafer 30. A mask 61 is disposed on the wafer 30. The mask 61 comprises or fully consists of a metal or an alloy or a composite material containing metal. A preferred material is aluminium or an aluminium alloy. The alloy may contain at least 90 weight percent of a metal or aluminium. 2 designates prepared cavities which are etched into the wafer up to a certain depth. The instantaneous depth is designated by T. The thickness D of the wafer may be a few hundred μm, for example between 150 and 600 μm. The height H of the mask layer 61 is less than 1 μm, preferably less than 500 nm. The walls may be formed substantially orthogonal. The angle α of a wall or all walls with respect to the bottom may be in a range of 85° to 95°. If desired, it may also be smaller than 90°. The cavity will then become wider to the bottom, and thinner partition walls remain between the cavities towards the bottom which may be advantageous when, for example, through etching is intended and the bridges between the cavities 2 are to hold membranes for a thermally insulated support of sensors (particularly infrared detectors).

An alternating supply of etching and passivation gas may be effected during the ICP etching into the depth of the wafer. This may be effected by the flow control 72, possibly depending on the higher ranking control 75. The gasses are supplied from the reservoirs 73 for the etching gas 74 and the passivation gas. The individual phases may respectively last several seconds (in particular less than 10 s, preferably less than 6 s, respectively) and follow each other directly. The evacuation may be carried out continuously.

FIG. 8 shows a schematic top view of a section of a wafer. A repetitive pattern of recesses is shown, the individual elements of the pattern being arranged along rows 95 and columns 94. The broken lines are only meant for visualisation and are not actually present. FIG. 8 shows the cavity contours which are all angular. In connection with the etching method described these, however, are also a subject matter of the invention. Instead of angular contours, however, fully or partly rounded contours may be etched as shown in FIG. 3.

Different recesses 91, 92 and 93 are provided per individual pattern. They correspond to omissions in the mask 96 which preferably completely covers the residual wafer surface and preferably also the (vertical) circumferential side of the wafer 30. In this way a plurality of homogenous recess patterns which are separated from each other after the formation of the recesses may be formed on a wafer simultaneously in one manufacturing step.

The area to be etched may cover at least 8%, preferably at least 20%, preferably more than 35% of the substrate surface. The substrate itself may be a disk-shaped wafer which may, for example, be substantially circular with a diameter of at least 10 cm, preferably at least 15 cm. The wafer itself may comprise or entirely consist of silicon. Preferably it consists of crystalline silicon.

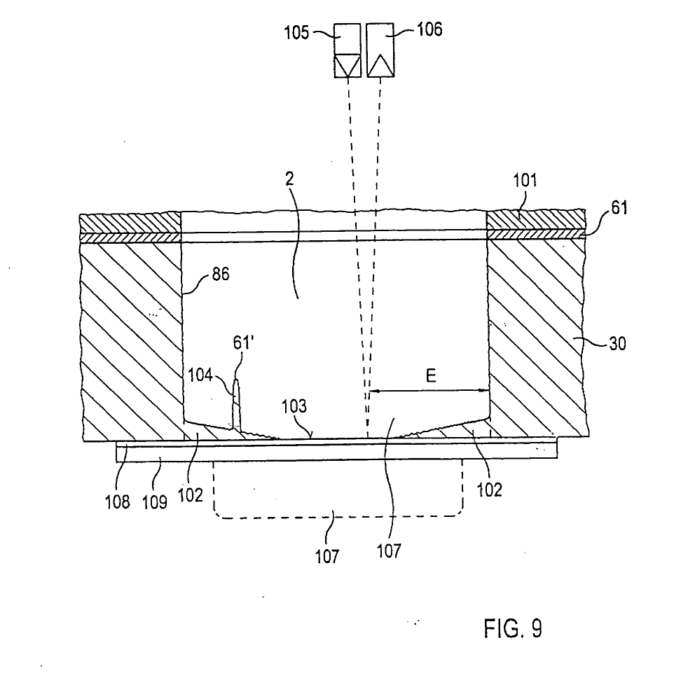

FIG. 9 shows ratios during through etching of a substrate or wafer 30. In the state shown the wafer is almost completely etched through from the top to the bottom. According to this embodiment an etching stop layer 108 was applied to the other substrate surface (the bottom surface in FIG. 9) in the area of the passage of the hole before the etching process, a thin membrane 109 on which later on (or immediately) a thermally insulated electronic component 107 to be supported may be formed being provided on said etching stop layer.

The etching process described above has lead to the result that more to the centre of the cavity 2 etching down to the etching stop layer 108 having a comparatively smooth surface 103 has been accomplished while rather in the corner portions parts 102 of the substrate material remain which have a comparatively rough surface. Sometimes needle formation may occur due to the re-deposition of mask particles.

A state as shown in FIG. 9 may be recognised by a depth sensor 105, 106. It may, for example, be a light source, particularly a laser light source 105 which preferably irradiates the centre (Distance E from the edge >20%, preferably >40% of the cross dimensions Q (diameter or edge length)) of the cavity 2. A sensor 106 evaluates the reflected light. The optical paths are schematically shown by broken lines. As long as laser light is reflected by the comparably rough surface of the substrate yet to be removed by etching (as schematically indicated by 102) the reflection is comparatively undirected, and therefore the reflected light received by the sensor is weak. When, on the other hand, etching stop layer 108 is exposed, generally starting in the centre, increasingly directed light is reflected by the then smoother surface 103 so that the intensity received by the sensor 106 increases.

Thus, for example, the intensity of the received reflected light can be checked for a threshold value. It is also possible to examine the first derivative (the change of the received signal) for a threshold value. The first derivative may be generated in discrete time. Generally the depth measurement may be carried out by evaluating the reflected light.

If the etching stop layer 108 is already partly exposed another etching method may be implemented; preferably an isotropic etching process is used to, on the one hand, protect the etching stop layer 108 and, on the other hand, remove needles 104 in the corner sections 102 by etching. This may still be effected by ICP. However, the gas pressure may be increased and/or the applied bias voltage can be reduced. By increasing the pressure the free path length will be reduced, and the moving direction of the ions is less strictly aligned with the field lines of the applied direct voltage field so that the etching process becomes more isotropic. By reducing the applied direct voltage a similar process will be achieved, i.e. a more isotropic etching process.

After said second etching process finally a third etching process may be implemented in which the applied bias voltage is preferably zero. Otherwise again dry etching and/or etching with inductively energy coupled plasma may be carried out. The third etching process is preferably isotropic.

After the termination of the etching process the mask 61 is removed. This may be effected by wet etching. Before that residual passivation agent (residual polymers) disposed on the mask may be removed. This may, for example, be effected by means of oxygen plasma. The mask itself can be removed in a wet chemical process, e.g. by a phosphoric acid etching mixture. Alternatively or afterwards a treatment with TMAH (tetramethyl ammonium hydroxide, preferably in an aqueous solution—TMAHW) may be carried out.

The material from which material is to be removed is preferably a circular crystalline waver having a diameter of at least 10, preferably at least 15 cm.

The mask material preferably comprises aluminium as its main component (ratio >90 weight percent, preferably >95 weight percent). Further components may be added, for example copper (quantity: 0.5 to 2 weight percent, preferably less than 1 weight percent) and/or silicon (quantity: 0.5 to 2 weight percent) and/or titanium (quantity: less than 3 weight percent, preferably less than 1.5 weight percent). The mask material is regarded as an independent part of the invention. Wafers fully or partly covered with such a mask material are also regarded as an independent part of the invention.

The invention may generally be used for depth structuring in micro mechanics, for example for manufacturing acceleration sensors with a shiftable mass or of IR sensors which are to be kept thermally insulated.

FIG. 10 schematically shows another embodiment. While in the embodiments according to FIGS. 1, 3 and 4 always one cavity and one membrane are provided for one sensor element, respectively, it is also possible to provide a plurality of sensor elements 124(1)-(8) capable of separately emitting signals above one cavity 122(1)-(4). In case of an equal size of the grid for the sensor elements an individual cavity would then be larger than the ones described above. Then also individual terminals 125(1)-(8) are to be provided for each sensor element, respectively. However, a plurality of sensor elements may be connected, particularly be connected in series, e.g. the ones arranged above the same cavity designed, e.g. to increase the signal intensity. 120 designates the virtual (not really existing) rows of the grid according to which the sensor elements are aligned. Again the contact surfaces of the terminals may be provided in the edge or corner sections.

Apart from following a rectangular grid the sensor elements may also be arranged in a triangular grid (60°) or a hexagonal grid (120°). In this case as well a plurality of sensor elements may be located above one cavity. In particular, two (see FIG. 10) or four sensor elements may be provided above one cavity in case of a rectangular grid. In case of a triangular grid (60°), it may, in particular, be two (one cavity in a rhombus of two triangles), four (one cavity in a large triangle consisting of four smaller triangles) or six (one cavity in a hexagon of six small triangles); and in case of a hexagonal grid, in particular, it may be six.

If several sensor elements are disposed above one cavity they will preferably remain physically connected and will then preferably be used in one sensor module comprising a plurality of sensor elements.

The conductor paths for connecting the sensor elements may be designed so that they extend in the area between the individual sensor elements, and they may also be larger (broader, higher) than required from electric aspects alone. They may then also act as heat insulation between the sensor elements by forming, on the one hand, a thermal capacity preventing heat transfer and signal falsification between the individual sensor elements as well as; on the other hand, deflecting heat along the conductor path and thus away from the sensor elements, which has the same effect.

The cavity may also be formed so that one or more bridges (“islands”) for the membrane positioned above it will remain in a cavity. Particularly in case of large cavities and correspondingly membranes for a plurality of sensor elements this may be reasonable. Such a bridge is indicated in FIG. 10.

A method for selectively removing material from the surface of a substrate for forming a cavity comprises the steps of applying a mask to the surface of the substrate in accordance with the desired selective removal and of dry etching the substrate, and it is characterised in that a metal, preferably aluminium, is used for forming the mask. During dry etching energy can be inductively coupled to the etching medium. The substrate may be spaced from the inductive coupling by at least twice, preferably at least trice the average free path length of the plasma atoms. The distance between the substrate and the inductive coupling can be kept at at least 10 cm. The pressure can be kept below 5 Pa, preferably below 3 Pa, during the etching process. Alternating etching and passivation steps for the side walls of the cavity may be carried out. Material can be removed down to a depth of at least 80 μm, preferably at least 300 μm. The material removal may be carried out down to the other side of the substrate. A mask having a thickness of less than 1.5 μm, preferably less than 0.6 μm may be formed. The substrate can be masked to the edge. The application of the mask may be effected by evaporating or sputtering the metal, preferably aluminium. When the mask is applied a metallic layer may be etched in accordance with the desired selective removal. The metal used may contain at least 90 weight percent Al. The etching position (T) in the direction of the depth can be repeatedly determined, in which case the etching process will be terminated or switched to a second etching process qualitatively differing from the previous etching process or operating with other operating parameters than the previous etching process when a certain position is reached. The depth may be determines using laser light the characteristics of which are evaluated after its reflection from the bottom, particularly referring to the first derivation from a detected signal. During the above mentioned second etching process dry etching with inductively energy coupled plasma may be carried out, the gas pressure being higher and/or the applied bias voltage being lower. After the second etching process a third etching process may be implemented which is qualitatively different or works under different operational parameters. In the third etching process dry isotropic etching may be carried out, preferably with inductively energy coupled plasma, and the applied bias voltage may be 0. Before the mask is removed an incineration step for polymer residues on the mask may be carried out, preferably by wet etching. The incineration may be effected with oxygen plasma. After the incineration a treatment with a phosphoric acid etching mixture and/or tetramethyl ammonium hydroxide may be carried out. The above method may have one or more of the following features:
the substrate contains Si, preferably crystalline silicon,
the material removal is carried out on more than 8%, preferably more than 20% of the substrate surface,
the substrate is a disk-shaped wafer having a diameter of at least 10 cm, preferably at least 15 cm.

Also the use of aluminium or an aluminium alloy containing at least 90 weight percent Al or a composite material containing at least 90 weight percent Al as a mask material for substrates to be dry etched with inductively energy-coupled plasma was described.

A mask material comprising aluminium for masking wafers to be etched contains a ratio of aluminium of more than 90 weight percent, preferably more than 95 weight percent and added copper in a ratio of 0.5 to 2 weight percent, preferably less than 1 weight percent and/or silicon in a ratio of 0.5 to 2 weight percent and/or titanium in a ratio of 0.2 to 3 weight percent, preferably less than 1.5 weight percent.

A wafer having a mask layer comprises a mask material as described above.

1-15. (canceled)

16. A radiation sensor comprising:
a support;
a cavity which may be a recess or a through hole formed in one surface of the support;
a sensor element formed above the cavity, preferably on a membrane covering the cavity; and
electric terminals for the sensor element, characterised in that:
the cavity in the surface of the support has a round or oval contour;
the side wall of the cavity is rectangular to the support surface; and
the cavity is formed through dry etching.

17. A radiation sensor according to claim 16, characterised in that the support has a rectangular and particularly a square contour.

18. A radiation sensor according to claim 17, characterised in that one or more electric terminals are provided in a corner section of the sensor.

19. A radiation sensor according to claim 16, characterised in that the sensor element is a thermopile.

20. A radiation sensor according to claim 16, characterised in that a plurality of sensor elements are formed above one cavity.

21. A radiation sensor according to claim 16, characterised by one or more of the following features:
the membrane material comprises a dielectric, particularly silica and/or silicon nitride;
under the membrane an etching stop layer containing an oxide, particularly silica, is provided; and
the support material contains silicon and/or GaAs and/or a semiconductor material.

22. A radiation sensor according to claim 16, characterised by one or more of the following dimensions:
support height H: more than 50 μm, preferably more than 200 μm, less than 1,500 μm, preferably less than 600 μm;
support edge length L: less than 2 mm, preferably less than 1.5 mm;
cavity diameter D: more than 55%, preferably more than 65% and/or less than 90%, preferably less than 80% of the support edge length; and
membrane thickness D: less than 3 μm, preferably more than 0.1 μm.

23. A wafer comprising a plurality of blanks for radiation sensors according to one or more of the preceding claims formed on it, characterised in that the blanks are arranged on the wafer in a rectangular, rhombic, triangular or hexagonal grid.

24. A sensor array comprising a plurality of radiation sensors according to one or more of claims 16 to 22.

25. A sensor array according to claim 24, characterised in that a plurality of radiation sensors are arranged in two or more rows and in two or more columns.

26. A sensor module comprising:
a radiation sensor according to one or more of claims 16 to 22;
a housing in which the radiation sensor accommodated;
an optical window in the housing; and
electric terminals protruding from the housing, said electric terminals being connected to the terminals.

27. A sensor module according to claim 26, characterised by an optical projection element, particularly a lens or a mirror.

28. A method for manufacturing a radiation sensor comprising the steps:
production of a plane wafer;
application of an etching stop layer on a first surface of the wafer and formation of a mechanically stable membrane on top of it;
application of an etching mask having one or more openings with oval or round contours on the second surface of the wafer; and
dry etching of cavities in the wafer from the second surface in the direction towards the etching stop layer such that the side wall of the cavity is rectangular to the support surface.

29. A sensor module comprising:
a sensor array according to claim 24;
a housing in which the sensor array is accommodated;
an optical window in the housing; and
electric terminals protruding from the housing, said electric terminals being connected to the terminals.

30. A sensor module according to claim 29, characterised by an optical projection element, particularly a lens or a mirror.
